(19) United States
(12) Patent Application Publication
(10) Pub. No.: US 2025/0140772 A1
(43) Pub. Date: May 1, 2025

(54) METHOD FOR BUILDING MODULES

(71) Applicant: Robert Bosch GmbH, Stuttgart (DE)

(72) Inventors: Christian Marc Lautensack, Tuebingen (DE); Mohamad Sayed, Reutlingen (DE)

(21) Appl. No.: 18/901,742

(22) Filed: Sep. 30, 2024

(30) Foreign Application Priority Data
Oct. 30, 2023 (DE) 10 2023 210 712.0

(51) Int. Cl. H01L 25/00; H01L 21/67

(52) U.S. Cl. CPC H01L 25/50; H01L 21/67144

(57) ABSTRACT

A method for building modules which are each provided with at least two electronic components. The method includes: defining a removal pattern that specifies a specific removal path for component positions on at least one wafer on which the components for building the modules are provided; initiating a removal process in which the components are removed from the at least one wafer along the removal path; initiating a building process in which the modules are provided with the removed components. The removal path is defined taking into account at least one correlation of electrical properties of the components and the component positions on the at least one wafer.

### CROSS REFERENCE

The present application claims the benefit under 35 U.S.C. § 119 of German Patent Application No. DE 10 2023 210 712.0 filed on Oct. 30, 2023, which is expressly incorporated herein by reference in its entirety.

### FIELD

The present invention relates to a method for building modules which are each provided with at least two electronic components. The present invention also relates to a computer program, a device and a system for this purpose.

### BACKGROUND INFORMATION

In the related art it is described that a picking pattern can be used to optimize the chip removal process in the manufacturing of symmetrical modules. This involves the use of a die bonder machine, for example, which automatically removes chips from a wafer as part of a pick & place process and inserts them into the intended modules. The picking pattern defines the order and orientation of the chips in the pick & place process, for instance. Symmetrical modules can be assemblies or components that comprise similar chips.

After the wafer has been manufactured, the chips are typically picked from the wafer and installed in the modules. The wafer manufacturing processes (e.g., slicing, polishing, lithography or etching) often result in a loss of quality for the chips, however.

### SUMMARY

The present invention provides a method, a computer program, a device, and a system. Further features and details of the present invention emerge from the disclosure herein. Features and details which are described in connection with the method according to the present invention will of course also apply in connection with the computer program according to the present invention, the device according to the present invention and the system according to the present invention, and respectively vice versa, so that mutual reference is or can always be made with respect to the disclosure of the individual aspects of the present invention.

In accordance with an example embodiment of the present invention, a method is provided for building modules, which are each provided with at least two electronic components, in particular semiconductor components, preferably power semiconductors. The modules can be power modules, for example, and the components can accordingly be semiconductors such as power semiconductors (e.g. MOSFETs). The modules can, for example, be used for inverters comprising multiple power modules.

One objective can generally be to reduce the size of the components, also referred to in the following as chips. Reducing the chip size goes hand with hand with an increase in temperature, however, so that this optimization objective is limited by the temperature development on the modules. It could be that the components on a module have an effect on the performance of the module, e.g. by influencing the temperature development. It is in particular the case that the more dissimilar the components with which the module is provided are, the more a higher temperature is favored. A targeted optimization of the removal pattern for selecting components with similar electrical properties can provide a solution here.

According to a first method step of the method according to an example embodiment of the present invention, a removal pattern can first be defined that specifies a specific removal path for component positions on at least one wafer on which the components for building the module are manufactured and/or provided. The removal path can be stored digitally, for example, so that it can be called up during an, in particular automated, removal process. Control commands for at least one motor, for example, can be generated based on the removal path. The removal process can then be initiated in accordance with a further method step. The components can be removed from the at least one wafer along the removal path, in particular in an automated manner.

According to an example embodiment of the present invention, the method according to the present invention further comprises another method step in which a building process, which may likewise be automated, can be initiated. In this step, the modules can be provided with the removed components. This step, too, can be carried out automatically.

According to the present invention, it can be provided that the removal path is defined taking into account at least one correlation of electrical properties of the components and the component positions on the at least one wafer. Electrical properties that can be taken into account include parameters such as RDSON, the threshold voltage VTH and/or QGD, for instance. RDS(ON) stands in particular for “drain-source on-resistance” and can refer to the resistance between the drain and source of a metal oxide semiconductor field-effect transistor (MOSFET) in the switched-on state. QGD stands in particular for “gate-drain charge” and can refer to the electrical charge that is transferred between the gate and the drain of a metal oxide semiconductor field-effect transistor (MOSFET) or a similar transistor type during the switching process. The electrical properties can be specific to switching losses and conduction losses, for example. The present invention is based in particular on the insight that switching losses resulting from similar components are themselves more similar as well. This is often advantageous. On the other hand, the more dissimilar the components are, the less favorable the operation of the module can be due to the temperature development. The removal path can in particular be defined in such a way that a module is provided with similar components so that the temperature during operation of the module can be reduced.

In the context of the present invention, it is furthermore possible that the removal path is defined as a path that alternates in opposite directions to provide a continuous and/or repeating and/or zigzag and/or sawtooth trajectory on the at least one wafer. In other words, the removal path can be defined taking into account the at least one correlation of the electrical properties of the components and the component positions on the at least one wafer by defining the removal path as a path that alternates in opposite directions. This has the advantage that components that are removed successively in the removal process have similar electrical properties as a result of the thus defined removal path, possibly even during a transition between two wafers. The modules are therefore provided with components that are electrically similar in order to be able to achieve a temperature optimization when the module is in operation. The removal pattern, i.e., the picking pattern, can moreover have the effect that it takes into account potential error zones on a wafer and thus ensures that only the qualitatively best chips are selected for assembly.

In the context of an example embodiment of the present invention, it can also be advantageous that the removal path is defined as a path that extends in a circular manner from an outer component position to an inner component position of the at least one wafer in order to provide a continuous and/or spiral trajectory on the at least one wafer. This makes it possible to define the removal path taking into account the at least one correlation of the electrical properties of the components and the component positions on the at least one wafer in such a way that components that are removed successively in the removal process have similar electrical properties.

In the context of an example embodiment of the present invention it can be provided that the removal path is defined as a path that includes a change of direction if a transition (from a current) to a subsequent wafer is provided during the removal. This makes it possible to define the removal path taking into account the at least one correlation of the electrical properties of the components and the component positions on the at least one wafer in such a way that components that are removed successively in the removal process have similar electrical properties even when there is a transition between wafers.

According to an example embodiment of the present invention, it is also possible that the removal path is defined as a path that extends in a circular manner with multiple changes of direction on the respective wafer in order to provide a continuous, semi-spiral trajectory on the at least one wafer. This, too, makes it possible to define the removal path taking into account the at least one correlation of the electrical properties of the components and the component positions on the at least one wafer in such a way that components that are removed successively in the removal process have similar electrical properties.

In the context of an example embodiment of the present invention the present invention it can further be provided that the following steps are initiated repeatedly when the removal process is being initiated:
removing the components along the removal path from a current wafer until the removal of the components for the current wafer is concluded,
carrying out a transition from the current wafer to a subsequent wafer,
removing the components along the removal path from the subsequent wafer until the removal of the components for the subsequent wafer is concluded.

The removal path can then be defined as a path in which the removal of the components ends after the conclusion of the removal at the same component position for the current wafer at which the removal for the subsequent wafer is continued. This, too, makes it possible to utilize the correlation of the electrical properties of the components and the component positions on the at least one wafer.

It is also advantageous if, in the context of an example embodiment of the present invention, a removal machine, e.g. in the form of a die bonder machine, is actuated for the removal of the components along the removal path. Alternatively or additionally, the electronic components can be embodied as semiconductor components, preferably power semiconductors, wherein the respective module is fitted with at least three components. The components can thus form a functional structure, e.g. for power electronics, which is optimized by the removal pattern according to the present invention.

Another subject matter of the present invention is a system for building modules which are provided with at least two electronic components. The system can comprise a device for defining a removal pattern. As in the method according to the present invention, the removal pattern can specify a specific removal path for component positions on at least one wafer. In the system according to the present invention, the components can be provided on the at least one wafer for building the module. The system according to the present invention can further comprise a removal machine for removing the components from the at least one wafer in a removal process.

According to an example embodiment of the present invention, it can be provided that the components are removed along the removal path in the removal process, wherein the removal path is defined taking into account at least one correlation of electrical properties of the components and the component positions on the at least one wafer. The system according to the present invention thus has the same advantages as those described in detail with reference to a method according to the present invention. The apparatus can also be embodied as a device according to the present invention for data processing.

Another subject matter of the present invention is a computer program, in particular a computer program product, comprising instructions that, when the computer program is executed by a computer, prompt said computer program to carry out the method according to the present invention. The computer program according to the present invention has the same advantages as those described in detail with reference to a method according to the present invention.

Another subject matter of the present invention can be device for data processing which is configured to carry out the method according to the present invention. The device can be a computer, for example, that executes the computer program according to the present invention. The computer can comprise at least one processor for executing the computer program. A non-volatile data memory can be provided as well, in which the computer program can be stored and from which the computer program can be read by the processor for execution.

Another subject matter of the present invention can be a computer-readable storage medium, which is part of the system according to the present invention and/or comprises the computer program according to the present invention and/or comprises instructions that, when executed by a computer, prompt said computer program to carry out the method according to the present invention. The storage medium is configured as a data memory such as a hard drive and/or a non-volatile memory and/or a memory card, for example. The storage medium can be integrated in the computer, for instance.

The steps of a method according to the present invention can be repeated and/or carried out automatically and/or in a computer-assisted manner. The method can also be configured as a computer-implemented method.

Further advantages, features and details of the present invention will emerge from the following description, in which embodiment examples of the present invention are described in detail with reference to figures. The features mentioned herein can each be essential to the present invention individually or in any combination.

### BRIEF DESCRIPTION OF THE DRAWINGS

FIG. 1 shows a schematic visualization of a method, a system, a storage medium and a computer program according to embodiment examples of the present invention.

FIG. 2 shows a schematic illustration of a temperature distribution for the manufactured module.

FIG. 3 shows a zigzag removal pattern.

FIG. 4 shows removal patterns according to embodiment examples of the present invention.

### DETAILED DESCRIPTION OF EXAMPLE EMBODIMENTS

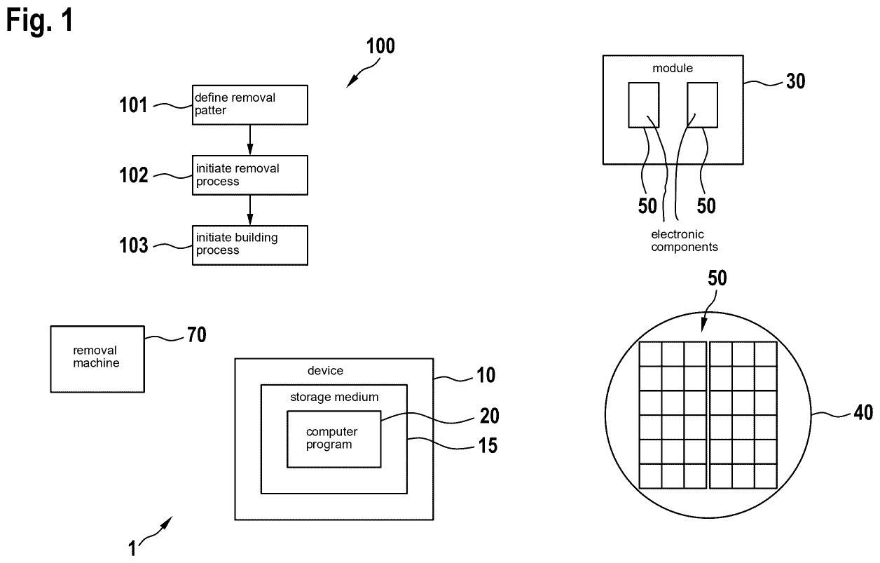

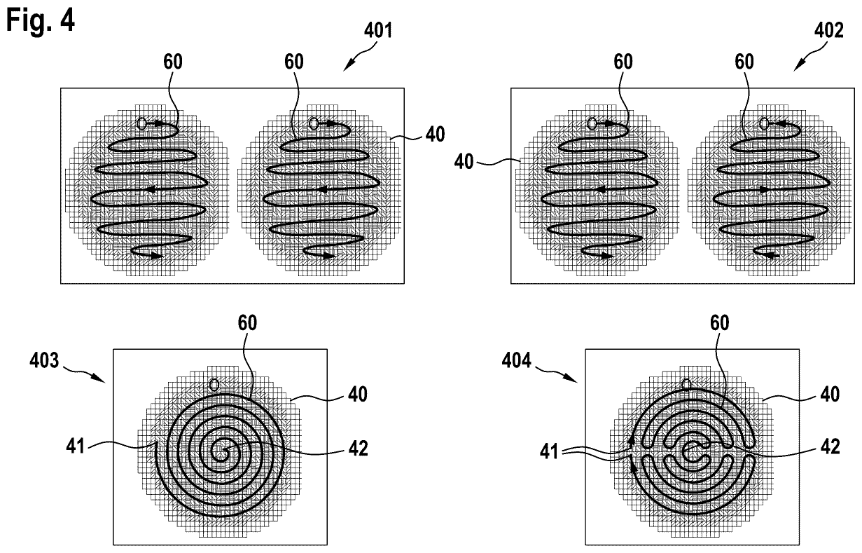

FIG. 1 schematically shows a system 1 comprising a device 10, a storage medium 15 and a computer program 20 according to embodiment examples of the present invention. According to embodiment examples of the present invention, FIG. 1 furthermore shows a method 100 for building modules 30, which are each provided with at least two electronic components 50, in particular semiconductor components, preferably power semiconductors. According to a first method step 101, a removal pattern, also referred to as a picking pattern, can first be defined that specifies a specific removal path 60 for component positions on at least one wafer 40 (see FIG. 4 which shows example removal paths 60) on which the components 50 are manufactured and provided for building the module 30. According to a second method step 102, a removal process can then be initiated, in which the components 50 are removed from the at least one wafer 40 along the removal path 60. According to a third method step 103, a building process can furthermore be initiated, in which the modules 30 are provided, e.g. fitted, with the removed components 50. It can be provided that the removal path 60 is defined taking into account at least one correlation of electrical properties of the components 50 and the component positions on the at least one wafer 40.

FIG. 1 moreover also shows a system 1 for building modules 30 according to design variants of the present invention. The system 1 can comprise a device 10 defining 101 a removal pattern and a removal machine 70 for removing the components 50 from the at least one wafer 40 in a removal process. In other words, the system 1 can be configured to carry out the method 100 according to the present invention.

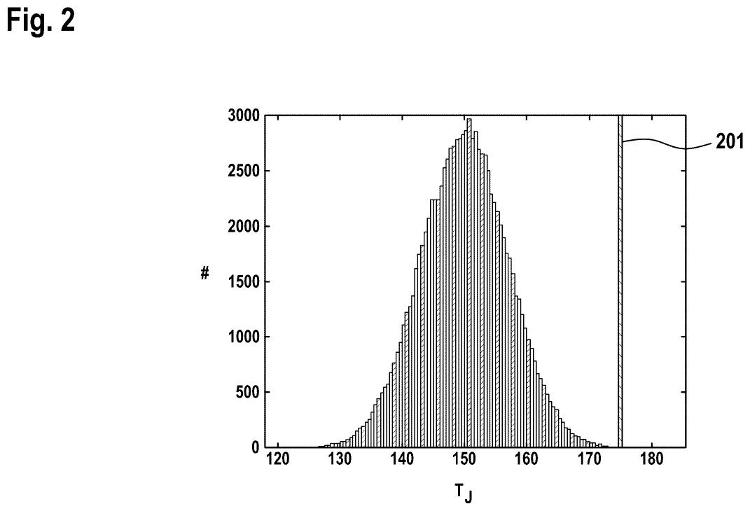

The present invention is in particular based on the consideration that it cannot simply be assumed that adjacent components 50, hereinafter also referred to as chips, have uncorrelated properties. Rather, the statistics and patterns found in the on-wafer measurement data can be used to define the picking approach and thus reduce tolerances within the modules. FIG. 2 shows an example graph, in which the temperature Tⱼ is plotted against the number of modules 30. The distribution for small values of Tⱼ and for high values of Tⱼ in the graph, shows reduced quantities and increased costs. In particular the extreme values of this distribution lead to significant cost increases and should therefore be minimized. 201 furthermore indicates the chip limit as the limit value.

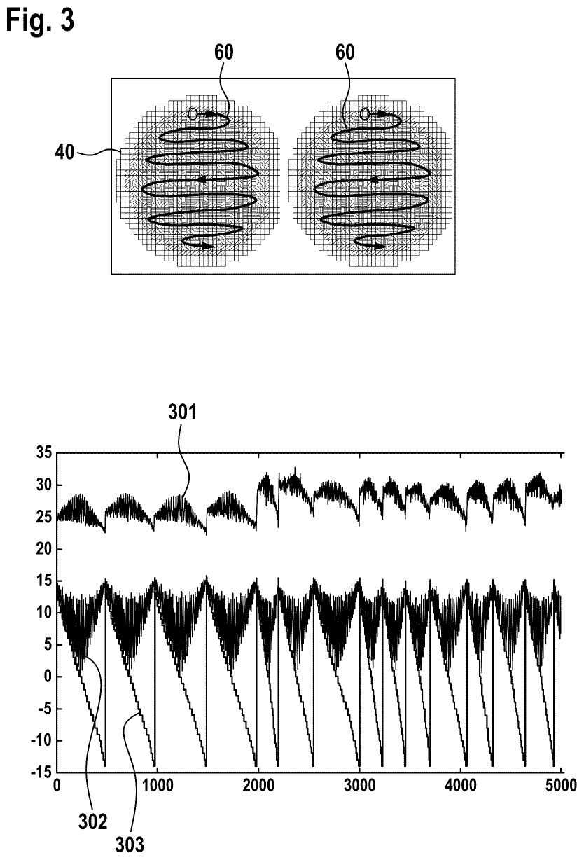

According to the present invention, an improved picking pattern for wafers can be proposed. FIG. 3 shows example measurements of a quality parameter of a chip as a function of the position of the chip on the wafer. The curve 301 can represent the quality parameter; for instance a measured variable or property of the chip. The quality parameter can accordingly be specific to the manufacturing process and/or a quality of the manufactured chip. This measured variable is “Qgd”, for example; i.e. in particular a gate-drain charge of the chip, or also R_{DS(ON)}. The curve 302 can indicate a radius on the wafer at which the chip is provided. The curve 303 can represent the vertical position of a point on the wafer, at which the chip is provided, in a Cartesian coordinate system. The correlation of the electrical property, in particular the quality parameter, with the position of the chips on the wafer is clearly visible in the measurements. The measurements were taken for a conventional zigzag pattern. The “zigzag pattern” for a “wafer's picking pattern” is in particular a specification of the order for selecting or checking chips on a wafer. For example, it is the specification that the chips are selected or checked in a zigzag order across the wafer.

According to design variants of the present invention, a modification of or alternatives to the conventional zigzag pattern are proposed. FIG. 4 first shows the conventional zigzag pattern 401. A modified zigzag pattern 402 with alternating y-direction, i.e. with a change of direction, a coil pattern 403 or a half-coil pattern 404, can be defined instead according to design variants of the present invention. It is thus possible to define new picking patterns, also referred to as removal patterns, taking into account the aforementioned correlations, and thus build symmetrical modules, achieve a narrower distribution and therefore also higher performance.

In FIG. 4, in the removal pattern 402, the removal path 60 is defined as a path that alternates in opposite directions to provide a continuous, repeating, zigzag or sawtooth trajectory on the at least one wafer 40.

In the removal pattern 403, the removal path 60 is defined as a path that extends in a circular manner from an outer component position 41 to an inner component position 42 of the at least one wafer 40 to provide a continuous, spiral trajectory on the at least one wafer 40.

In the removal pattern 404, the removal path 60 is defined as a path that extends in a circular manner with multiple changes of direction on the respective wafer 40 to provide a continuous, semi-spiral trajectory on the at least one wafer 40.

The above explanation of the embodiments describes the present invention solely within the scope of examples. Of course, individual features of the embodiments can be freely combined with one another, if technically feasible, without leaving the scope of the present invention.

What is claimed is:

1. The method for building modules which are each provided with at least two electronic components, comprising the following steps:
defining a removal pattern that specifies a specific removal path for component positions on at least one wafer on which the components for building the modules are provided;
initiating a removal process in which the components are removed from the at least one wafer along the removal path; and
initiating a building process in which the modules are provided with the removed components;
wherein the removal path is defined taking into account at least one correlation of electrical properties of the components and the component positions on the at least one wafer.

2. The method according to claim 1, wherein the removal path is defined as a path that alternates in opposite directions to provide a continuous or repeating or zigzag or sawtooth trajectory on the at least one wafer.

3. The method according to claim 1, wherein the removal path is defined as a path that extends in a circular manner from an outer component position to an inner component position of the at least one wafer to provide a continuous, spiral trajectory on the at least one wafer.

4. The method according to claim 1, wherein the removal path is defined as a path that includes a change of direction when a transition to a subsequent wafer is foreseen during the removal.

5. The method according to claim 1, wherein the removal path is defined as a path that extends in a circular manner with multiple changes of direction on the at least one wafer to provide a continuous, semi-spiral trajectory on the at least one wafer.

6. The method according to claim 1, wherein the following steps are initiated repeatedly when the removal process is being initiated:
removing the components along the removal path from a current wafer until the removal of the components for a current wafer is concluded;
carrying out a transition from the current wafer to a subsequent wafer;
removing the components along the removal path from the subsequent wafer until the removal of the components for the subsequent wafer is concluded;
wherein the removal path is defined as a path in which the removal of the components ends after a conclusion of the removal at the same component position for the current wafer at which the removal for the subsequent wafer is continued.

7. The method according to claim 1, wherein a removal machine is actuated for the removal of the components along the removal path.

8. The method according to claim 1, wherein the electronic components are embodied as semiconductor components, wherein a respective module is fitted with at least three components.

9. A non-transitory computer-readable medium on which is stored a computer program including instructions for building modules which are each provided with at least two electronic components, the instructions, when executed by a computer, causing the computer to perform the following steps:
defining a removal pattern that specifies a specific removal path for component positions on at least one wafer on which the components for building the modules are provided;
initiating a removal process in which the components are removed from the at least one wafer along the removal path; and
initiating a building process in which the modules are provided with the removed components;
wherein the removal path is defined taking into account at least one correlation of electrical properties of the components and the component positions on the at least one wafer.

10. A device for data processing, for building modules which are each provided with at least two electronic components, the device configured to:
define a removal pattern that specifies a specific removal path for component positions on at least one wafer on which the components for building the modules are provided;
initiate a removal process in which the components are removed from the at least one wafer along the removal path;
and initiate a building process in which the modules are provided with the removed components;
wherein the removal path is defined taking into account at least one correlation of electrical properties of the components and the component positions on the at least one wafer.

11. A system for building modules which are provided with at least two electronic components, comprising:
a device configured to define a removal pattern that specifies a specific removal path for component positions on at least one wafer on which the component for building the module are provided; and
a removal machine configured to remove the components from the at least one wafer in a removal process, in which the components are removed along the removal path;
wherein the removal path is defined on the at least one wafer taking into account at least one correlation of electrical properties of the components and the component positions.
